(19) United States
(12) Patent Application Publication
(10) Pub. No.: US 2024/0232448 A1
(43) Pub. Date: Jul. 11, 2024

(54) THERMAL FLUID SUBSYSTEMS DIGITAL TWIN

(71) Applicant: NORTHROP GRUMMAN SYSTEMS CORPORATION, FALLS CHURCH, VA (US)

(72) Inventors: Jonathan Paul Curry, Melbourne, FL (US); Erich Mirabal, Malabar, FL (US); Jorge M Gonzalez, Melbourne, FL (US)

(21) Appl. No.: 18/153,107

(22) Filed: Jan. 11, 2023

(51) Int. Cl. G06F 30/15; G06F 30/27

(52) U.S. Cl. CPC G06F 30/15; G06F 30/27

(57) ABSTRACT

A system and method for generating and integrating surrogate neural network models developed from physics models of several subsystems on a vehicle, such as an aircraft, and simulating the integration of the models in a virtual flight deck (VFD). The method includes modeling each of the subsystems as a physics model, developing a surrogate neural network model from each of the physics models, placing the surrogate neural network models on a common bus, and integrating some or all of the surrogate neural network models provided on the bus in the VFD.

### BACKGROUND

### Field

This disclosure relates generally to a system and method for generating and integrating surrogate neural network models developed from physics models of several vehicle subsystems and, more particularly, to a system and method for generating and integrating surrogate neural network models developed from physics models of several subsystems on an aircraft and simulating the integration of the models in a virtual flight deck (VFD).

### Discussion of the Related Art

Modern aircraft design and testing employs model-based engineering and system simulation. Model-based design captures and tracks aircraft requirements early in the design process and then continues to document the requirements and check compliance. The modeling process separately models the various subsystems on the aircraft, such as fuel subsystems, aero subsystems, hydraulics subsystems, environmental control subsystems (ECS), etc.

Known model-based design simulators have a number of drawbacks. For example, known model-based design simulators isolate the subsystems, where data from the subsystems are typically manually shared and rarely integrated, and have fragile architectures with rigid connections between components. Further, known simulators are computationally intensive, limiting and sometimes intractable. Also, simulations and analyses are based on discrete-point sampling and not on continuous curves, and thus are subject to larger interpolation errors or dependent on the test flight phase for experimental data. Further, current model-based design simulators are impractical to co-simulate more than a limited set of subsystems within the physics based platform. Currently software exists to model physics based subsystems and these models can be scaled up to include multiple domains using, for example, Matlab, AMEsim, Flowmaster, etc. However, when simulating high frequency models like a hydraulic actuation subsystem with a low frequency ECS the runtimes become untenable. There is currently no method to overcome the scaling problem of integration of all the thermal fluid subsystems into one model for model-based aircraft design.

### SUMMARY

The following discussion discloses and describes a system and method for generating and integrating surrogate neural network models developed from physics models of several subsystems on a vehicle, such as an aircraft, and simulating the integration of the models in a virtual flight deck (VFD). The method includes modeling each of the subsystems as a physics model, developing a surrogate neural network model from each of the physics models, placing the surrogate neural network models on a common bus, and integrating some or all of the surrogate neural network models provided on the bus in the VFD.

Additional features of the disclosure will become apparent from the following description and appended claims, taken in conjunction with the accompanying drawings.

### BRIEF DESCRIPTION OF THE DRAWINGS

FIG. 1 is a block diagram of a system that illustrates a platform for designing, simulating and testing a vehicle and that includes a digital twin that generates and integrates surrogate neural network models of vehicle subsystems;

FIG. 2 is a block diagram of the digital twin showing the integration of the surrogate neural network models by a virtual flight deck (VFD); and

FIG. 3 is a neural network model generated by the digital twin.

### DETAILED DESCRIPTION OF THE EMBODIMENTS

The following discussion of the embodiments of the disclosure directed to a system and method for generating and integrating surrogate neural network models developed from physics models of several subsystems on an aircraft and simulating the integration of the models in a virtual flight deck (VFD) is merely exemplary in nature, and is in no way intended to limit the disclosure or its applications or uses. For example, the vehicle being modeled and simulated as described herein is an aircraft. However, the system and method may be applicable for other vehicles.

As will be discussed in detail below, this disclosure proposes a system and method for virtual simulation of a vehicle, such as an aircraft, that employs a common data bus architecture to share information between models of the subsystems on the vehicle. Each of the subsystems on the vehicle is developed and modeled in a classical physics model technique that includes a network one-dimensional bulk average physics based approximations. Once the subsystem models are created, each of the subsystems is parsed into stand-alone models or “trainers”. The stand-alone models are simulated with random inputs through machine learning until a neural network model is able to achieve the same output response as the physics based models. The neural network models are then used to replace the physics based models in a vehicle level simulation. This allows the co-simulation of all thermal fluid subsystems within a vehicle model to be executed together and inter-subsystem interactions to be observed.

A physics model is software structure that illustrates the movement of objects. A neural network is a software structure that can learn to perform tasks by processing examples, without being programmed with any task-specific rules. A neural network generally includes neurons or nodes that each has a “weight” that is multiplied by the input to the node to obtain a probability of whether something is correct. More specifically, each of the nodes has a weight that is a floating point number that is multiplied with the input to the node to generate an output for that node that is some proportion of the input. The weights are initially “trained” or set by causing the neural networks to analyze a set of known data under supervised processing and through minimizing a cost function to allow the network to obtain the highest probability of a correct output. A neural network often includes several layers of nodes that perform nonlinear processing, where each successive layer receives an output from the previous layer. Generally, the layers include an input layer that receives raw data from a sensor, a number of hidden layers that extract abstract features from the data, and an output layer that identifies a certain thing based on the feature extraction from the hidden layers. One popular type of neural network is known as a convolutional neural network (CNN) that is a type of feedforward neural network that may be utilized to model data associated with input data having a grid-like topology.

A machine learning program, machine learning algorithm, or machine learning module, as used herein, is generally a type of artificial intelligence including one or more algorithms that can learn and/or adjust parameters based on input data provided to the algorithm. In some instances, machine learning programs, algorithms and modules are used at least in part in implementing artificial intelligence (AI) functions, systems and methods. A machine learning program may be configured to implement stored processing, such as decision tree learning, association rule learning, artificial neural networks, recurrent artificial neural networks, long short term memory networks, inductive logic programming, support vector machines, clustering, Bayesian networks, reinforcement learning, representation learning, similarity and metric learning, sparse dictionary learning, genetic algorithms, k-nearest neighbor (KNN), and the like. One type of algorithm suitable for use in machine learning modules as described herein is an artificial neural network or neural network, taking inspiration from biological neural networks. An artificial neural network can learn to perform tasks by processing examples, without being programmed with any task-specific rules. The artificial intelligence systems and structures discussed herein may employ deep learning. Deep learning is a particular type of machine learning that provides greater learning performance by representing a certain real-world environment as a hierarchy of increasing complex concepts. Deep learning typically employs a software structure comprising several layers of neural networks that perform nonlinear processing, where each successive layer receives an output from the previous layer.

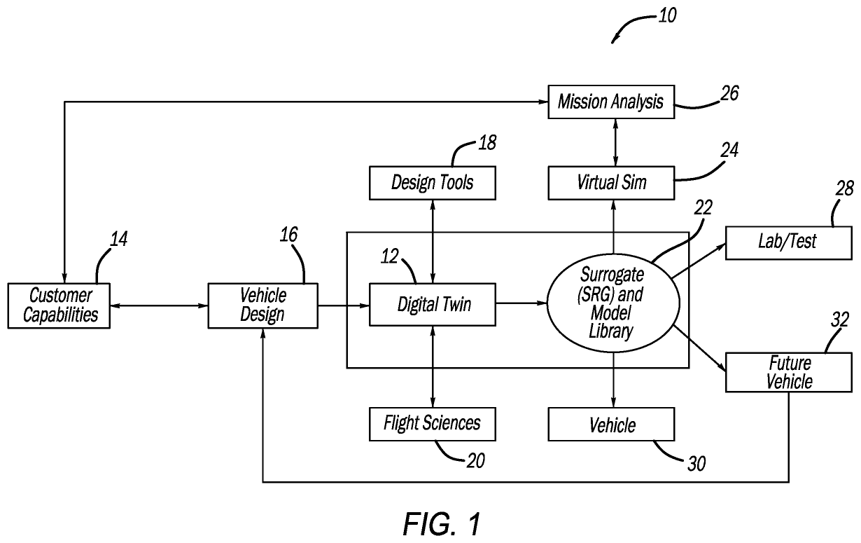

FIG. 1 is a block diagram of a system 10 that illustrates a platform for designing, simulating and testing a vehicle. For the discussion herein, the vehicle is an aircraft. However, the system 10 will have application for designing, simulating and testing other types of vehicles, such as land and sea vehicles. The simulated integration of the various subsystems on the vehicle referred to above is developed in a digital twin 12. At box 14, the various parameters, requirements, capabilities, etc. of the vehicle are identified by, for example, a customer, and coordinated with a process for generating a conceptual design of the vehicle at box 16 based on those parameters. Various CAD designs of the configuration and layout of the vehicle and its subsystem are generated at box 18 and aerodynamic and propulsion configurations and characteristics of the vehicle are modeled at box 20. The conceptual design of the vehicle, the CAD designs and the aerodynamic and propulsion models are provided to the digital twin 12 to be integrated and simulated, where the simulation provides feedback to the CAD designs and the aerodynamic and propulsion models over any suitable protocol, such as model based engineering (MBE). MBE is the use of analysis and simulation tools throughout a product lifecycle to reduce the use of physical prototypes. As will be discussed in further detail below, the various models of the various subsystems are integrated in the digital twin 12 in a less comprehensive manner through the use of neural networks and physics models.

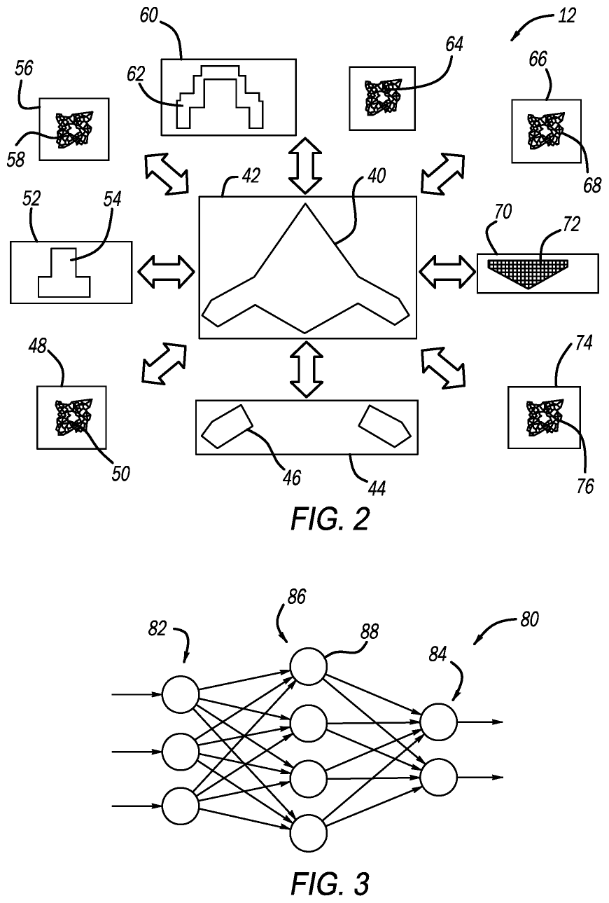

FIG. 2 is a block diagram of the digital twin 12 illustrating the various virtual subsystems that are part of a digital aircraft 40 being designed and simulated on a virtual flight deck (VFD) 42. Each subsystem is initially modeled as a physics based model and that model is then used to develop and train a surrogate neural network model through machine learning. The physics models and/or the surrogate neural network models are then integrated by the VFD 42. In this non-limiting example, the subsystems include a hydraulics subsystem 44 that has been modeled by a physics model 46; a heat exchanger subsystem 48 that has been modeled by a surrogate neural network model 50; a fuel subsystem 52 that has been modeled by a physics model 54; a RAM air subsystem 56 that has been modeled by a surrogate neural network model 58; an ECS 60 that has been modeled by a physics model 62 or a surrogate neural network model 64; an environments subsystem 66 that has been modeled by a surrogate neural network model 68; a propulsion subsystem (engine) 70 that has been modeled by a physics model 72; and an aerodynamic subsystem 74 that has been modeled by a surrogate neural network model 76. The arrows between the subsystems 44, 48, 52, 56, 60, 66, 70 and 74 represent a common bus architecture that provides the interconnection and integration of the various models as simulated in the VFD 42.

FIG. 3 is a neural network 80 illustrating an example of a surrogate neural network model generated by the VFD 42 that is an integration of some or all of the models of the subsystems 44, 48, 52, 56, 60, 66, 70 and 74 referred to above. The neural network 80 includes an input layer 82, an output layer 84 and a hidden layer 86 therebetween, where the layers 82, 84 and 86 include nodes 88. Integrating the various vehicle subsystem models 46, 50, 54, 58, 62, 64, 68, 72 and 76 in the VFD 42 as discussed provides for scalable interconnections between the vehicle subsystems 44, 48, 52, 56, 60, 66, 70 and 74, allows simulation of the subsystems 44, 48, 52, 56, 60, 66, 70 and 74 using machine learning which allows scalable integration, allows integration of all thermal fluid vehicle subsystems, aerodynamic subsystems and propulsion subsystems while keeping physics-based fidelity, and integrates mission level analysis with detailed subsystem analysis.

Returning to FIG. 1, all of the various surrogate neural network models of the vehicle subsystems 44, 48, 52, 56, 60, 66, 70 and 74 provided to the digital twin 12 are stored in a repository 22 to be used for other vehicles and other design platforms, if desirable. For example, the surrogate neural network models can be provided to a flight simulator 24 that may interact with a mission analysis process at box 26, where the mission analysis may be controlled by the various parameters, requirements and capabilities of the vehicle at the box 14. Further, the surrogate neural network models may be employed in a lab environment at box 28 where testing on the various vehicle subsystems and software may be performed. The surrogate neural network models can also be placed on the vehicle itself once it is produced at box 30 so that the simulation data can be compared to actual performance of the vehicle for a comparison between what should be happening to what is happening. The surrogate neural network models can also be placed on the vehicles that are developed in the future at box 32.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. A method for virtually designing and testing a vehicle, said vehicle including a plurality of vehicle subsystems, said method comprising:
modeling each of the subsystems as a physics model;
developing a surrogate neural network model from each of the physics models;
placing the surrogate neural network models on a common bus; and
integrating some or all of the surrogate neural network models provided on the bus.

2. The method according to claim 1 wherein integrating some or all of the surrogate neural network models includes simulating the subsystems in a virtual simulator.

3. The method according to claim 1 wherein the vehicle is an aircraft.

4. The method according to claim 3 wherein the plurality of vehicle subsystems include a hydraulics subsystem, a heat exchanger subsystem, a fuel subsystem, a RAM air subsystem, an environmental control subsystems (ECS), an environments subsystem, a propulsion subsystem and an aerodynamic subsystem.

5. The method according to claim 3 wherein integrating some or all of the surrogate neural network models includes integrating the surrogate neural networks in a virtual flight deck (VFD) and simulating the subsystems in the VFD.

6. The method according to claim 1 further comprising storing the surrogate neural network models in a repository to be used by other systems.

7. The method according to claim 6 wherein the other systems include one or more of a flight simulator, a mission analysis processor, a lab environment and an actual vehicle.

8. A method for virtually designing and testing an aircraft, said aircraft including a plurality of subsystems, said method comprising:
modeling each of the subsystems as a physics model;
developing a surrogate neural network model from each of the physics models;
placing the surrogate neural network models on a common bus;
integrating some or all of the surrogate neural network models provided on the bus in a virtual flight deck (VFD); and
simulating the subsystems in the VFD.

9. The method according to claim 8 wherein the plurality of subsystems include a hydraulics subsystem, a heat exchanger subsystem, a fuel subsystem, a RAM air subsystem, an environmental control subsystems (ECS), an environments subsystem, a propulsion subsystem and an aerodynamic subsystem.

10. The method according to claim 8 further comprising storing the surrogate neural network models in a repository to be used by other systems.

11. The method according to claim 10 wherein the other systems include one or more of a flight simulator, a mission analysis processor, a lab environment and an actual aircraft.

12. A system for virtually designing and testing a vehicle, said vehicle including a plurality of vehicle subsystems, said system comprising:
means for modeling each of the subsystems as a physics model;
means for developing a surrogate neural network model from each of the physics models;
means for placing the surrogate neural network models on a common bus; and
means for integrating some or all of the surrogate neural network models provided on the bus.

13. The system according to claim 12 wherein the means for integrating some or all of the surrogate neural network models simulates the subsystems in a virtual simulator.

14. The system according to claim 12 wherein the vehicle is an aircraft.

15. The system according to claim 14 wherein the plurality of vehicle subsystems include a hydraulics subsystem, a heat exchanger subsystem, a fuel subsystem, a RAM air subsystem, an environmental control subsystems (ECS), an environments subsystem, a propulsion subsystem and an aerodynamic subsystem.

16. The system according to claim 14 wherein the means for integrating some or all of the surrogate neural network models integrates the surrogate neural networks in a virtual flight deck (VFD) and simulates the subsystems in the VFD.

17. The system according to claim 12 further comprising means for storing the surrogate neural network models in a repository to be used by other systems.

18. The system according to claim 17 wherein the other systems include one or more of a flight simulator, a mission analysis processor, a lab environment and an actual vehicle.
